(19) United States
(12) Patent Application Publication
(10) Pub. No.: US 2015/0047783 A1
(43) Pub. Date: Feb. 19, 2015

(54) PRESSURE TRANSFER PLATE FOR PRESSURE TRANSFER OF A BONDING PRESSURE

(71) Applicants: Jurgen Burggraf, Scharding (AT); Peter-Oliver Hangweier, Pram (AT); Christian Perau, Altheim (AT)

(72) Inventors: Jurgen Burggraf, Scharding (AT); Peter-Oliver Hangweier, Pram (AT); Christian Perau, Altheim (AT)

(73) Assignee: EV GROUP E. THALLNER GMBH, St. Florian am Inn (AT)

(21) Appl. No.: 14/386,046

(22) PCT Filed: Mar. 19, 2012
(86) PCT No.: PCT/EP2012/054808

§ 371 Date: Nov. 5, 2014

(51) Int. Cl. H01L 21/67; B23K 20/02

(52) U.S. Cl. CPC H01L 21/67121; B23K 20/023
USPC 156/308.2; 156/580

(57) ABSTRACT

A pressure transfer plate for transferring a bonding pressure, especially in thermocompression bonding, from a pressurization apparatus to a wafer, comprising a first pressure side for making contact with a pressurization apparatus, a second pressure side facing away from the first pressure side having an effective contact area for making contact with the wafer and pressurizing it, at least the effective contact area having a low adhesiveness relative to the wafer.

### FIELD OF THE INVENTION

The invention relates to a pressure transfer disk (plate) for transferring a bonding pressure, especially in thermocompression bonding, from a pressurization apparatus to a wafer.

### BACKGROUND OF THE INVENTION

One of the innumerable bond methods is thermocompression bonding. In this type of bonding method, two wafers are permanently joined/bonded to one another at very high pressures and temperatures. In order to obtain a bonding interface which is as uniform as possible, the tools, the bond chucks (bond sample holders) and the pressure disks are produced with surface roughnesses which are as low as possible. Preferably, these tools have no surface roughness at all, are perfectly planar and have no defects, as much as possible. To level possible macroscopic unevenness and/or ripples, leveling disks, for example graphite disks, can be attached on one or both sides of the pressure disks. These leveling disks are soft and deformable. In the bond process, the leveling disks are accordingly located between the pressure disk and the tool which lies behind it and/or the top of a wafer which is to be bonded.

For most bonding methods, the leveling disks perform their task of leveling unevenness. They do this mainly by efficient filling of the space between the leveling disk and the wafer. But in thermocompression bonding, the problem arises that the compensation of unevenness by this filling as a result of high pressure and temperatures is so efficient that the wafers remain suspended on the pressure disk or leveling disk. If the bond chamber is opened after the bond process, it thus occurs that the wafer is damaged by it. The damage takes place mainly due to the wafer's adhering to the surface of the pressure disk or the leveling disk when the bond chamber is opened and losing adhesion spontaneously after a few milliseconds to seconds. For this reason, the wafer falls back, undergoes impact and is damaged. It is therefore the object of this invention to devise a pressure transfer disk with which damage can be avoided during bonding, especially when the bonded wafer is removed from the bonding device.

This object is achieved with the features of claims 1 and 10. Advantageous developments of the invention are given in the dependent claims. All combinations of at least two of the features given in the specification, the claims and/or the figures also fall within the scope of the invention. At the given value ranges, values within the indicated limits will also be considered to be disclosed as boundary values and will be claimed in any combination.

### SUMMARY OF THE INVENTION

The invention is based on the idea of facilitating the release of the wafer from the pressurization apparatus and of thus avoiding damage by attaching to the pressurizing apparatus a pressure transfer disk (plate) which is of low adhesion relative to wafers, i.e., between the pressure transfer disk and the wafer. By reducing the adhesion, the wafer can be released from the respective pressure disk after bonding without adhesion causing damage to the wafer, for example by falling down. As claimed in the invention, a reliable release from the pressure transfer disk while maintaining the remaining advantageous properties is ensured.

As used herein, adhesiveness designates a certain retaining force per m² which, as claimed in the invention, should be as low as possible so that the overwhelming part of the fixing of the substrate on the receiving surface is caused by fixing means in the fixing section.

If the adhesion between two solids, which are joined to one another, is to be determined, the energy which is required to drive a crack through the solid can be measured. In the semiconductor industry, the so-called “razor blade test” or “Maszara razor blade test” is often used. This test, strictly speaking, is a method for determining the bonding energy between two solids. Generally, the solids are welded to one another. As claimed in the invention, other measurement methods are preferably used in order to determine the adhesiveness of a layer at this point, which should be of low adhesion relative to as many different materials as possible. The most frequently used measurement method is the contact angle method.

The contact angle method is used together with the Young equation in order to obtain evidence about the surface energy of a solid by using a test liquid. This method qualifies the surface energy of a surface by a certain test liquid, generally by water. Corresponding measurement methods and the evaluation methods are known to one skilled in the art. The contact angle, which is determined with the contact angle method, can be converted to a surface energy in N/m or J/m². For relative comparison of different surfaces for the same test liquid, the information about the contact angle is sufficient to obtain a (relative) estimate of the adhesiveness of the surface. Thus, by using water as the test liquid, it can be stated that wetted surfaces which produce a contact angle on the water droplet of roughly 30° have higher adhesion (strictly speaking only to water) than surfaces whose contact angle on the water droplet has roughly 120°.

The embodiment as claimed in the invention will be preferably used to pressurize Si wafers. Therefore, a determination of the surface energy of any low adhesion layer used to Si would be desirable. Since Si is not liquid at room temperature, as mentioned above, a test liquid is used to characterize the low adhesion layer with respect to this test liquid. All following contact angle values and/or surface energies are thus values which quantify the low adhesion layer according to the invention with respect to a test liquid and allow at least relative evidence about the adhesiveness to other substances, preferably solids, even more preferably Si.

In one preferred embodiment of the invention, the adhesiveness is defined by a surface energy of less than 0.1 J/m², especially less than 0.01 J/m², preferably less than 0.001 J/m², even more preferably less than 0.0001 J/m², ideally less than 0.00001 J/m².

Alternatively or additionally, according to one advantageous embodiment of the invention, the adhesiveness of the contact area is defined with a contact angle greater than 20°, especially greater than 50°, preferably greater than 90°, even more preferably greater than 150°. The adhesiveness of a surface to another material can be determined using the aforementioned contact angle method. Here a droplet of a known liquid, preferably water (values as claimed in the invention relative to water) (alternatively glycerin or hexadecane), is deposited on the surface to be measured. Using a microscope the angle is measured exactly from the side, specifically the angle between the tangent on the droplet and the surface.

According to another advantageous embodiment of the invention, the pressure transfer disk is made as a lattice network, having a mesh width M less than 2 mm, preferably less than 1 mm, more preferably less than 0.5 mm, even more preferably less than 0.1 mm, most preferably less than 0.01 mm. As will be appreciated by those skilled in the art in the field, the optimum mesh width can also depend on the diameter and the thickness of the wafer and can be empirically determined in particular by tests. The antiadhesion action is caused by the very small, but finite mesh width M. According to the present invention, the mesh width M is small enough to transfer the homogenous pressure distribution of the pressure transfer apparatus in the best possible manner to a surface of the wafer. At the same time, it reduces the absolute contact area such that an adhesion of the wafer on the pressure transfer apparatus, especially on an upper tool, is no longer possible or is at least smaller than the force due to the weight of the wafer.

Alternatively or in addition, according to one aspect of the invention, at least the contact area of the second pressure side has a surface roughness produced e by shotpeening, sandblasting, grinding, etching and/or polishing between 100 nm and 100 especially between 1 μm and 10 even more preferably between 3 μm and 5 μm. The surface roughness can be referenced to the wafer thickness and/or the wafer diameter. It is conceivable that for a certain wafer diameter and/or a certain wafer thickness there is an optimum roughness. According to the present invention, the latter is accordingly determined empirically. In one preferred embodiment, the surface roughness is produced wet-chemically. By using acids, the surface is eroded in a controlled manner. A surface with corresponding roughness is produced by the indicated methods shotpeening, sandblasting, grinding and/or polishing with correspondingly large grain sizes. The resulting effect of the antiadhesion action is similar to the effect of the lattice network, only that in this case not a regular mesh structure, but an irregular surface causes the desired effect of low adhesion.

It is known from nanotechnology that low adhesion surfaces in the microrange and/or the nanorange, whose morphology contributes to the low adhesion or even causes it have extreme unevenness. One example, which is known to one skilled in the art, is the so-called “lotus blossom effect.”

To the extent the pressure transfer disk is formed from a material which is thermodynamically stable up to at least 400° C., especially up to at least 800° C., preferably up to at least 1200° C., even more preferably up to at least 2000° C., still more preferably up to at least 3000° C., the pressure transfer disk can advantageously be used in thermocompression bonding.

It is especially advantageous if the pressure transfer disk is formed from a material which has a uniform and high compressive strength over a large temperature range, especially at temperatures above 400° C., which strength is greater than 100 MPa, especially greater than 500 MPa, preferably greater than 1000 MPa, even more preferably greater than 2000 MPa. The compressive strength can be increased especially by boundary means on the lateral periphery of the pressure disk (at least biaxial compressive strength).

Conceivable material classes would be the following:
high temperature plastics,
ceramics, SiC, SiN, etc.
metals,
refractory metals,
thermal stability steels,
general tool steels
or any combination of the aforementioned materials.

According to the invention, the pressure transfer disk advantageously has a certain elasticity/deformability so that unevenness or ripple of the wafer and/or of the pressure transfer apparatus is leveled when pressure is applied.

According to another advantageous embodiment, the pressure transfer disk has a thickness d less than 15 mm, preferably less than 10 mm, more preferably less than 5 mm, even more preferably less than 1 mm, most preferably less than 0.1 mm, most preferably of all less than 0.05 mm.

Furthermore, it is advantageous if in one development of the invention at least the second pressure side, preferably the entire pressure transfer disk, is formed from a material which is inert relative to the wafer under given conditions and or does not react with the wafer material and/or is not soluble relative to the wafer material. Especially for wafers, which have logic families which are highly sensitive to metallic impurities, the concentration of the corresponding chemical elements at least on the second pressure side, preferably in the entire pressure transfer disk, is below predetermined boundary values. In the special case of CMOS, compatibility the material of the pressure transfer disk is preferably free of the alloying elements Au, Cu, Ag.

A reduction and/or adjustment of a low adhesiveness can also be achieved, especially in combination with the other measures, by controlled definition of air channels along the surface, so that the formation of vacuum on the contact area is minimized or prevented. In another embodiment, the leveling disk has a rough surface for the access of gas molecules between the wafer and the leveling disk. A vacuum between the wafer and the leveling disk is thus prevented by producing a rough surface by the aforementioned methods.

The features described for the pressure transfer disk should also be considered disclosed as features of the described application and vice versa.

An application of the above described pressure transfer disk to bonding, especially thermocompression bonding, is also disclosed as an independent invention.

Other advantages, features and details of the invention will become apparent from the following description of preferred exemplary embodiments as well as using the drawings; the views are schematic.

### BRIEF DESCRIPTION OF THE DRAWINGS

FIG. 1 shows a schematic cross sectional view of a bond device using a pressure transfer disk according to the invention,

FIG. 2a shows a plan view of a first embodiment of the pressure transfer disk according to the invention,

FIG. 2b shows a schematic cross sectional view of the first embodiment of the pressure transfer disk,

FIG. 3a shows a plan view of a second embodiment of the pressure transfer disk according to the invention, and

FIG. 3b shows a schematic cross sectional view of the second embodiment of the pressure transfer disk.

### DETAILED DESCRIPTION OF PREFERRED EMBODIMENTS

In the figures, advantages and features of the invention are identified with reference numbers which identify them according to embodiments of the invention. Components or features with the same or equivalent function are identified with identical reference numbers.

In the figures, the features of the invention are not shown true to scale, in order to be able to represent the function of the individual features. The relationships of the individual components are partially disproportionate.

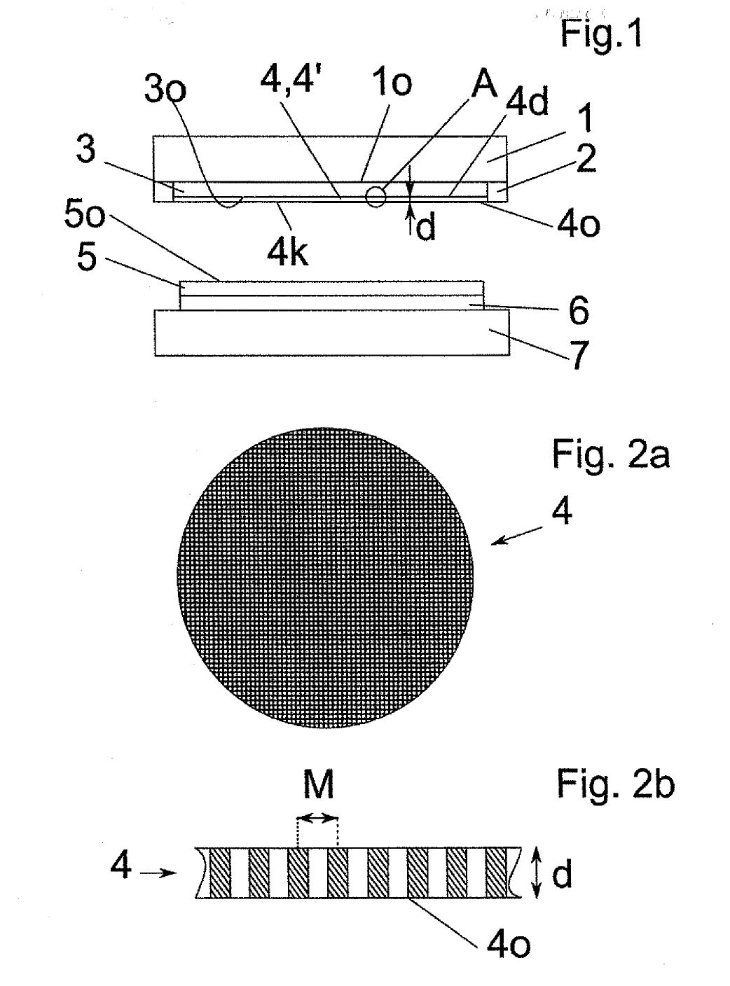

FIG. 1 shows a bond device for bonding of a first wafer 5 to a second wafer 6 which are accommodated for this purpose on a receiving apparatus, here a chuck 7, and are fixed by vacuum strips, clamps, etc.

The bond device can also especially have a bond chamber (not shown) in which the components which are shown in FIG. 1 are or can be accommodated and in which a defined atmosphere, especially high temperatures and high pressure or negative pressure (vacuum), can be produced.

Above the wafer pair of the first wafer 5 and the second wafer 6, there is provided a pressurizing apparatus 1 which can be aligned relative to the wafer pair and with which a bond pressure or a bond force can be applied to the wafer pair. Corresponding control apparatus for opposite alignment and uniform pressurization are known to one skilled in the art.

On the side 1o of the pressurization apparatus 1 facing the wafer pair, a leveling disk 3, formed as a graphite disk, is fixed by fixing means 2 on the pressurizing apparatus 1. The leveling disk 3 is used to level unevenness of the wafers 5, 6 or of the wafer pair. On the side 3o of the leveling disk 3, facing away from the pressurizing apparatus 1, a pressure transfer disk or plate 4, according to the invention, is fixed, in particularly likewise by the fixing means 2. The pressure transfer disk has a first pressure side 4d with which it is in contact with the side 3o. Furthermore, the pressure transfer disk 4 has a second pressure side 4o facing away from the first pressure side 4d for making contact with the wafer pair, namely, the wafer 5 on its surface 5o.

In the illustrated embodiment, the leveling disk 3 and the pressure transfer disk 4 on their lateral periphery have essentially identical dimensions which essentially correspond with the dimensions of the wafers 5, 6, at most slightly exceed them or fall below them.

The fixing means 2 fix the leveling disk 3 and the pressure transfer disk 4 from their lateral periphery, clamping on the side edge of the second pressure side 4o also being contemplated.

The region of the second pressure side 4o, which enters into contact with the wafer 5, is the effective contact area 4k which in this exemplary embodiment agrees with the second pressure side 4o.

Preferably, pressure transfer disks 4, 4′ have diameters of 4 inches, 6 inches, 8 inches, 12 inches, or 18 inches so that they correspond to current industrial sizes of wafers. Other diameters are also contemplated.

One embodiment of the pressure transfer disk 4 which is shown enlarged in cross section in FIG. 2b. FIG. 2b is an enlarged cross section according to enlargement A from FIG. 1, which enlargement A is shown in FIG. 2a. In this embodiment, pressure transfer disk 4 is made as a lattice network. The antiadhesion action or low adhesion force is caused by a very small, but finite mesh width M. The mesh width M is small enough to relay a homogeneous pressure distribution of the leveling disk 3 in the best possible manner to the surface 5o of the wafer 5. The illustrated embodiment reduces the absolute contact area, i.e., the effective contact area 4k, between the pressure transfer disk 4 and the wafer 5 so that the adhesion action of the pressure transfer disk 4 relative to the wafer 5 is minimized and becomes so small by corresponding material choice that the wafer pair no longer adheres to the pressure transfer disk 4.

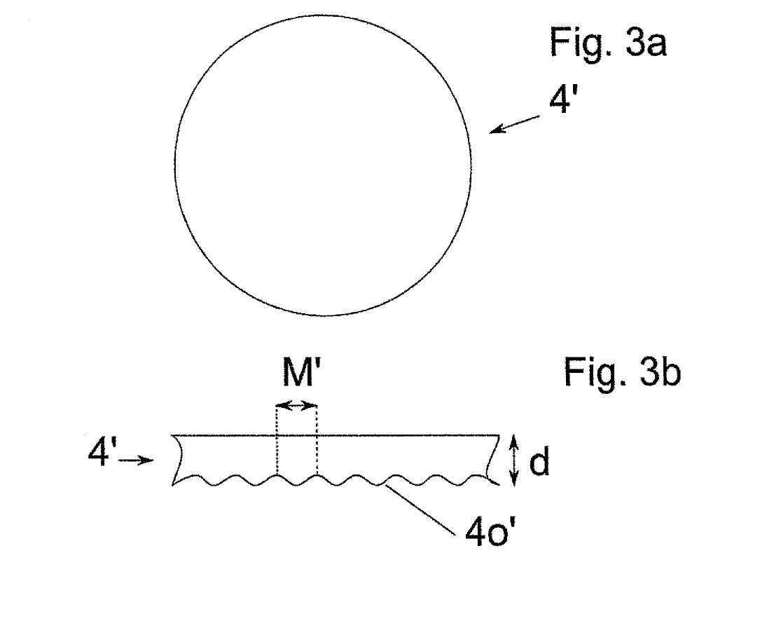

In the embodiment shown in FIGS. 3a and 3b, the pressure transfer disk 4′ is made as a sheet or foil, wherein the second pressure side 4o′ has a high surface roughness. The surface roughness can be produced especially wet-chemically. The surface 4o′ is eroded by the controlled used of acid. In particular, subsequently or exclusively a decided surface roughness can be produced by shotpeening, sandblasting, grinding and/or polishing with correspondingly large grain sizes.

In the interaction of the pressure transfer disk 4′ with the leveling disk 3, nevertheless a good pressure distribution and uniform bond force application are enabled.

Here the pressure transfer disk 4′ is elastic enough to be adapted to the unevenness of the overlying leveling disk 3 and/or of the wafer 5 which is to be exposed to the bond force.

The material for the pressure transfer disks 4, 4′ is especially steels and/or refractory metals, especially their alloys. Preferably high temperature steels are used.

The pressure transfer disks 4, 4′ have a thickness d in order to enable sufficient bending strength for fixing from one side, specifically via the fixing means 2. The fixing means 2 have in particular fixing elements which are arranged distributed on the periphery of the pressure transfer disk 4, 4′.

Fixing means can also be a direct connection to the leveling disk 3, especially by high temperature adhesives and/or embedding of the material of the pressure transfer disk 4, 4′ in a graphite matrix of the leveling disk 3. According to another embodiment, the lattice network according to the embodiment of FIGS. 2a and 2b and the graphite layer 3 will have a serial bond, viewed in the pressure direction, especially by embedding the especially metallic lattice network into the softer graphic layer 3.

### REFERENCE NUMBER LIST

1 pressurizing apparatus

1o side

2 fixing means

3 leveling disk

3o side

4, 4′ pressure transfer disk

4o, 4o′ second pressure side

4d first pressure side

4k contact area

5 first wafer

5o surface

6 second wafer

7 chuck

d thickness

M mesh width

M′ surface roughness

1-10. (canceled)

11. A pressure transfer disk for transferring a bonding pressure, especially in thermocompression bonding, from a pressurization apparatus to a wafer
a first pressure side for making contact with the pressurization apparatus,
a second pressure side facing away from the first pressure side, said second pressure side having an effective contact area for making contact with the wafer and pressurizing it, at least the effective contact area having a low adhesiveness relative to the wafer, wherein the pressure transfer disk is made as a lattice network.

12. The pressure transfer disk as claimed in claim 11, wherein the adhesiveness is defined by a surface energy of less than 0.1 J/m².

13. The pressure transfer disk as claimed in claim 11, wherein the adhesiveness of the contact area is defined with a contact angle greater than 20°.

14. The pressure transfer disk as claimed in claim 11, wherein the lattice network has a mesh width M less than 2 mm.

15. The pressure transfer disk as claimed in claim 11, wherein at least the contact area of the second pressure side has a surface roughness M′ between 100 nm and 100 μm, produced by one of the following: shotpeening, sandblasting, grinding, etching and/or polishing.

16. The pressure transfer disk as claimed in claim 11, wherein the pressure transfer disk is formed from a material which is thermodynamically stable up to at least 400° C.

17. The pressure transfer disk as claimed in claim 11, wherein the pressure transfer disk is formed from a material which especially over a large temperature range has a uniform and high compressive strength, at temperatures above 400° C., which strength is greater than 100 MPa.

18. The pressure transfer disk as claimed in claim 11, wherein the pressure transfer disk has a thickness d less than 15 mm.

19. The pressure transfer disk as claimed in claim 11, wherein at least the second pressure side is formed from a material which is inert relative to the wafer under given conditions and/or does not react with the wafer material and/or is not soluble relative to the wafer material.

20. An application of a pressure transfer disk as claimed in claim 11 during bonding, in particular in thermocompression bonding.
